(19) United States
(12) Patent Application Publication
(10) Pub. No.: US 2008/0237792 A1
(43) Pub. Date: Oct. 2, 2008

(54) SEMICONDUCTOR CAPACITOR STRUCTURE AND LAYOUT PATTERN THEREOF

(76) Inventors: Han-Chang Kang, Taipei Hsien (TW); Ta-Hsun Yeh, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 12/050,174

(22) Filed: Mar. 18, 2008

(30) Foreign Application Priority Data
Mar. 26, 2007 (TW) 096110376

(51) Int. Cl. H01L 29/92; H01L 23/48

(52) U.S. Cl. 257/532; 257/773; 257/E29.343; 257/E23.01

(57) ABSTRACT

The present invention provides a metal-oxide-metal (MOM) capacitor structure having a plurality of symmetrical ring type sections. The MOM capacitor structure of the present invention does not need photomasks above standard CMOS process, and thus the process cost is cheaper. In addition, due to the semiconductor process improvement, a significantly large number of metal layers can be stacked in the MOM capacitor structure, and since the distance between the metal layers becomes smaller, the unit capacitance will be increased.

### BACKGROUND OF THE INVENTION

1. Field of the Invention

The present invention relates to a semiconductor capacitor structure, and more particularly, to a metal-oxide-metal (MOM) type capacitor structure having a plurality of symmetrical ring type sections.

2. Description of the Prior Art

In semiconductor manufacturing processes, metal capacitors constituted by metal-insulator-metal (MIM) capacitor structures are widely applied in Ultra Large Scale Integration (ULSI) designs. Due to their lower resistance, less significant parasitic effect, and absence of induced voltage shift in the depletion region, metal capacitors with MIM capacitor structure are usually adopted as the main choice of semiconductor capacitor designs.

However, since the manufacturing cost for the MIM capacitor structure is very expensive, mainly due to the additional photomask(s) required in the manufacturing process, and as the cost becomes more significant along with development of advanced semiconductor manufacturing process technologies, an interdigitated metal capacitor of metal-oxide-metal (MOM) structure, which only engages in the standard CMOS manufacturing process, has been developed in accordance with a requirement for a more economical semiconductor manufacturing process technology. Applications of interdigitated metal capacitors have already been disclosed and discussed in various literatures, such as U.S. Pat. No. 6,784,050, U.S. Pat. No. 6,885,543, U.S. Pat. No. 6,974,744, U.S. Pat. No. 6,819,542, and Taiwan Patent No. 222,089 (the Taiwan counterpart patent of U.S. Pat. No. 6,819,542), whose contents are incorporated herein by reference.

In U.S. Pat. No. 6,819,542, a multilevel interdigitated metal structure is defined, wherein the multilevel interdigitated metal structure includes at least a plurality of odd layers, a plurality of even layers, and a plurality of dielectric layers. The plurality of odd layers and the plurality of even layers comprise a first electrode and a second electrode. The first electrode in the plurality of odd layers is coupled to the first electrode in the plurality of even layers through a first bus. Likewise, the second electrode in the plurality of odd layers is coupled to the second electrode in the plurality of even layers through a second bus.

In U.S. Pat. No. 6,819,542 (hereinafter “the '542 Patent”), a multilevel interdigitated metal structure is defined. Please refer to FIG. 1 and FIG. 2 together. FIG. 1 is a simplified diagram of an odd layer 10 of a multilevel interdigitated metal structure as shown in FIG. 5B of the '542 Patent. FIG. 2 is a simplified diagram of an even layer 20 of a multilevel interdigitated metal structure as shown in FIG. 6B of the '542 Patent.

As shown in FIG. 1, the odd layer 10 comprises a first electrode 11 and a second electrode 15. The first electrode 11 includes a first section 12, and a plurality of second sections 13 arranged in parallel. The first section 12 includes a first portion 12A and a second portion 12B. The first portion 12A and the second portion 12B respectively constitute the two strokes of the L-shaped first section 12. The plurality of parallel-arranged second sections 13 join the first portion 12A of the first section 12, and are separated from one another by a predetermined distance. The second electrode 15 includes a first section 16, and a plurality of second sections 17 arranged in parallel. The first section 16 includes a first portion 16A and a second portion 16B. The first portion 16A and the second portion 16B respectively constitute the two strokes of the L-shaped first section 16. The plurality of parallel-arranged second sections 17 join the first portion 16A of the first section 16, and are separated from one another by a predetermined distance. The plurality of second sections 13 of the first electrode 11 and the plurality of second sections 17 of the second electrode 15 interdigitate with each other in parallel.

As shown in FIG. 2, the even layer 20 includes a first electrode 21 and a second electrode 25. The first electrode 21 includes a first section 22, and a plurality of second sections 23 arranged in parallel. The first section 22 includes a first portion 22A and a second portion 22B. The first portion 22A and the second portion 22B respectively constitute the two strokes of the L-shaped first section 22. The plurality of parallel-arranged second sections 23 join the first portion 22A of the first section 22, and are separated from one another by a predetermined distance. The second electrode 25 includes a first section 26, and a plurality of second sections 27 arranged in parallel. The first section 26 includes a first portion 26A and a second portion 26B. The first portion 26A and the second portion 26B respectively constitute the two strokes of the L-shaped first section 26. The plurality of parallel-arranged second sections 27 join the first portion 26A of the first section 26, and are separated from one another by a predetermined distance. The plurality of second sections 23 of the first electrode 21 and the plurality of second sections 27 of the second electrode 25 interdigitate with each other in parallel. The second section 13 of the first electrode 11 in FIG. 1 is perpendicular to the second section 23 of the first electrode 21 in FIG. 2.

However, for the interdigitated metal capacitors described in U.S. Pat. No. 6,819,542 and the other above-mentioned patents, since the plurality of parallel structures of each electrode in the respective interdigitated metal capacitors are all electrically connected to each other through a structure perpendicular to them in the periphery, the geometrical symmetry of the interdigitated metal capacitors is not optimized, and will therefore not have satisfactory electrical characteristic.

### SUMMARY OF THE INVENTION

It is therefore one of the objectives of the present invention to provide a semiconductor capacitor structure having a plurality of symmetrical ring type sections and an improved geometrical symmetry, and thus the semiconductor capacitor structure of the present invention can attain a better capacitance effect and have a higher unit capacitance than conventional designs.

In accordance with an embodiment of the present invention, a semiconductor capacitor structure is disclosed. The semiconductor capacitor structure includes a first metal layer, a second metal layer and a dielectric layer. The first metal layer includes a first portion and a second portion, and the second metal layer includes a third portion and a fourth portion. The dielectric layer is formed between the first metal layer and the second metal layer. The first portion includes: a plurality of first sections arranged in parallel to one another, the plurality of first sections having turns or curves; a plurality of second sections arranged in parallel to one another, the plurality of second sections having turns or curves; and a third section, coupled to the plurality of first sections and the plurality of second sections. The second portion includes: a plurality of fourth sections arranged in parallel to one another, the plurality of fourth sections having turns or curves; a plurality of fifth sections arranged in parallel to one another, the plurality of fifth sections having turns or curves; and a sixth section, coupled to the plurality of fourth sections and the plurality of fifth sections. The plurality of first sections and the plurality of fourth sections interdigitate with each other in parallel, and the plurality of second sections and the plurality of fifth sections interdigitate with each other in parallel. The third portion includes: a plurality of seventh sections arranged in parallel to one another, the plurality of seventh sections having turns or curves; a plurality of eighth sections arranged in parallel to one another, the plurality of eighth sections having turns or curves; and a ninth section, coupled to the plurality of seventh sections and the plurality of eighth sections. The fourth portion includes: a plurality of tenth sections arranged in parallel to one another, the plurality of tenth sections having turns or curves; a plurality of eleventh sections arranged in parallel to one another, the plurality of eleventh sections having turns or curves; and a twelfth section, coupled to the plurality of tenth sections and the plurality of eleventh sections. The plurality of seventh sections and the plurality of tenth sections interdigitate with each other in parallel, and the plurality of eighth sections and the plurality of eleventh sections interdigitate with each other in parallel.

In accordance with an embodiment of the present invention, a semiconductor capacitor structure is disclosed. The semiconductor capacitor structure includes a third section; a plurality of first sections, wherein each first section is coupled to the third section, extends outward from a side of the third section and respectively develops along one of a plurality of first contours; a plurality of second sections, wherein each second section is coupled to the third section, and extends outward from another side of the third section and respectively develops along one of a plurality of second contours; a sixth section; a plurality of fourth sections, wherein each fourth section is coupled to the third section, and extends outward from a side of the sixth section and respectively develops along one of a plurality of fourth contours; and a plurality of fifth sections, wherein each fifth section is coupled to the third section, and extends outward from another side of the sixth section and respectively develops along one of a plurality of fifth contours.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a simplified diagram of an odd layer of a multilevel interdigitated metal structure according to the conventional art.

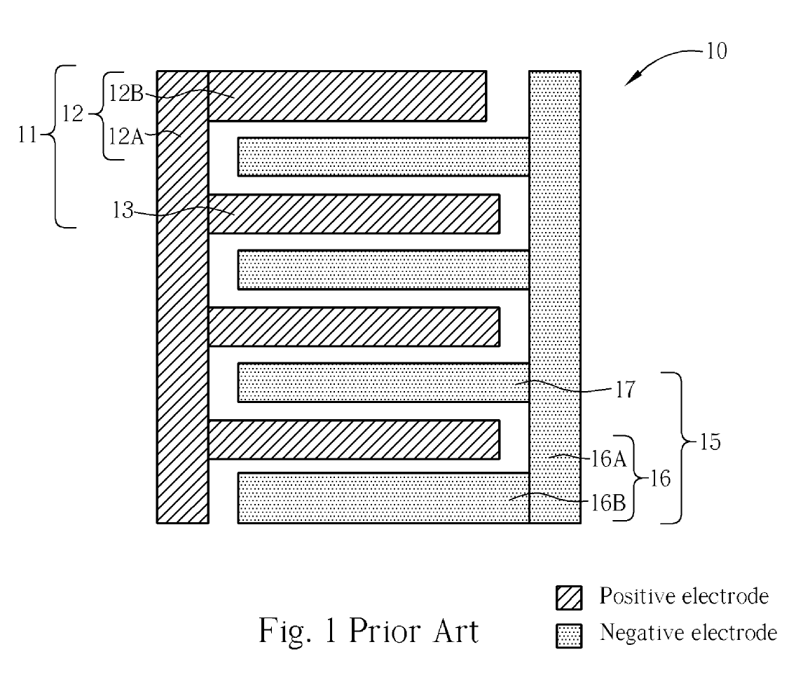

FIG. 2 is a simplified diagram of an even layer of a multilevel interdigitated metal structure according to the conventional art.

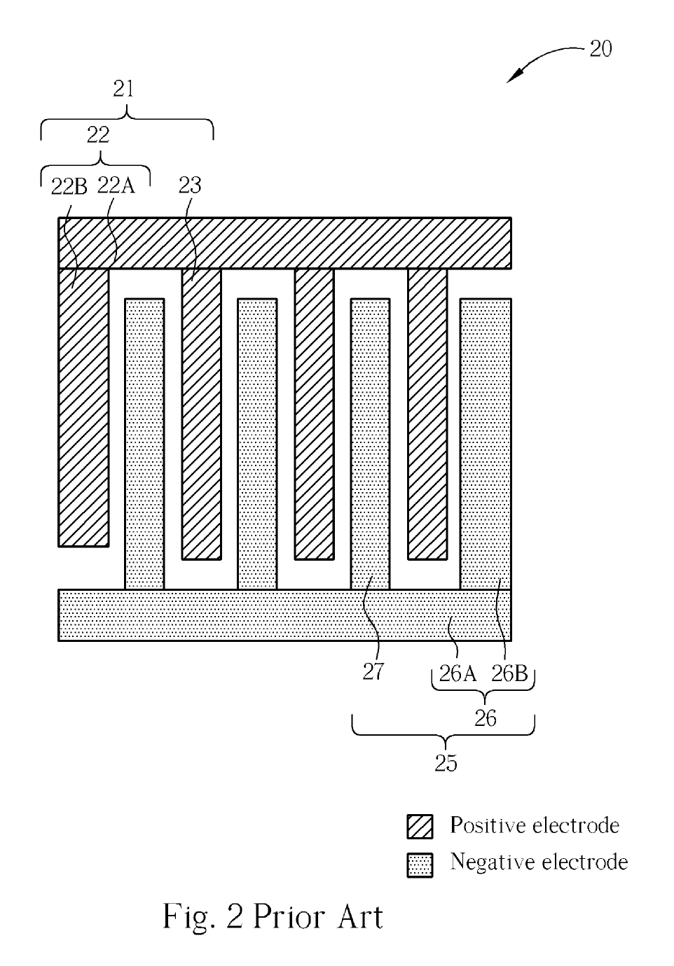

FIG. 3 is a simplified diagram of an odd metal layer of a semiconductor capacitor structure in accordance with an embodiment of the present invention.

FIG. 4 is a simplified diagram of an even metal layer in accordance with an embodiment of the present invention, which, when implemented together with the odd metal layer shown in FIG. 3, formulates a semiconductor capacitor structure.

FIG. 5 is a simplified diagram of another even metal layer in accordance with another embodiment of the present invention, which, when implemented together with the odd metal layer shown in FIG. 3, formulates a semiconductor capacitor structure.

FIG. 6 is a simplified diagram of an odd metal layer of a semiconductor capacitor structure in accordance with yet another embodiment of the present invention.

FIG. 7 is a simplified diagram of an odd metal layer of a semiconductor capacitor structure in accordance with yet another embodiment of the present invention.

FIG. 8 is a simplified diagram of an odd metal layer of a semiconductor capacitor structure in accordance with yet another embodiment of the present invention.

FIG. 9 is a simplified diagram of an odd metal layer of a semiconductor capacitor structure in accordance with yet another embodiment of the present invention.

FIG. 10 is a simplified diagram of an odd metal layer of a semiconductor capacitor structure in accordance with yet another embodiment of the present invention.

### DETAILED DESCRIPTION

The semiconductor capacitor structures described in the embodiments of the present invention adopt the capacitor manufacturing technologies embodying metal-oxide-metal (MOM) capacitor structures, which do not require additional process cost above the standard CMOS manufacturing process, as a preferred realization scheme thereof. In other words, the capacitors in the embodiments of the present invention include metal layers as conductive material and oxide layers as dielectric material. As will be appreciated by those of ordinary skill in the pertinent art, however, the realization of the core concept of the present invention is not necessarily limited to the disclosed embodiments as hereinafter described. Other known or novel conductive materials or dielectric materials can also be applied to implement the capacitor structure of the present invention.

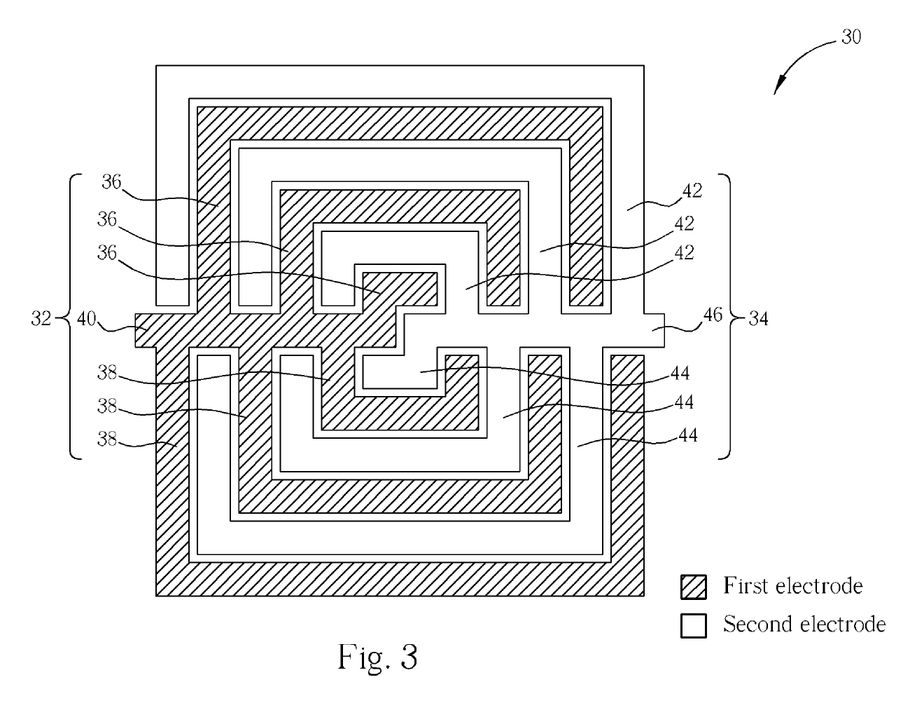

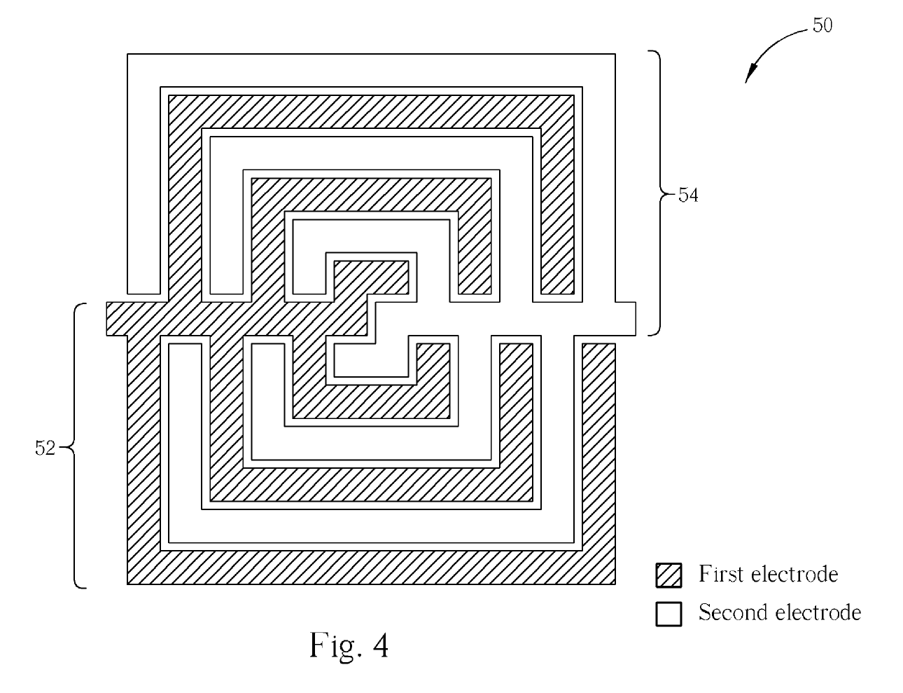

Please refer to FIG. 3 and FIG. 4 together. FIG. 3 is a simplified diagram of an odd metal layer 30 of a semiconductor capacitor structure in accordance with an embodiment of the present invention, and FIG. 4 is a simplified diagram of an even metal layer 50 of the semiconductor capacitor structure in accordance with the embodiment of the present invention. In general, the semiconductor capacitor structure in accordance with the embodiment of the present invention is formulated by interlacing and stacking a plurality of the odd metal layers 30 shown in FIG. 3 and a plurality of the even metal layers 50 shown in FIG. 4. In other words, an even metal layer 50 is superimposed on top of an odd metal layer 30, and another odd metal layer 30 is further superimposed on top of the even metal layer 50, and this scheme continues in the same way in order to make up the semiconductor capacitor structure by interlacing and stacking a plurality of the odd metal layers 30 and a plurality of the even metal layers 50. In addition, an oxide layer is introduced as a dielectric layer between each of the odd/even metal layers 30 and its adjacent even/odd metal layers 50. A person of average skill in the pertinent art should understand that a single odd metal layer 30 and a single even metal layer 50 are sufficient to constitute a working semiconductor capacitor structure.

As shown in FIG. 3, the odd metal layer 30 includes a first portion 32 and a second portion 34, wherein the first portion 32 and the second portion 34 respectively constitute two electrodes of the semiconductor capacitor structure of the present invention, and an oxide layer is utilized as a dielectric layer between the first portion 32 and the second portion 34. In this embodiment, the first portion 32 includes a plurality of first sections 36 arranged in parallel to one another, a plurality of second sections 38 arranged in parallel to one another, and a third section 40, wherein the third section 40 is coupled to the plurality of first sections 36 and the plurality of second sections 38. The plurality of first sections 36 and the plurality of second sections 38 are respectively positioned at either side of the third section 40 (as shown in FIG. 3, the plurality of first sections 36 are positioned at the upper side of the third section 40, and the plurality of second sections 38 are positioned at the lower side of the third section 40). The plurality of first sections 36 and the plurality of second sections 38 respectively develop along a specific contour (such as a contour with turns, curves, or other non-straight lines), and consequently form a part of a ring type structure (such as a square ring type structure shown in FIG. 3).

The second portion 32 includes a plurality of fourth sections 42 arranged in parallel to one another, a plurality of fifth sections 44 arranged in parallel to one another, and a sixth section 46, wherein the sixth section 46 is coupled to the plurality of fourth sections 42 and the plurality of fifth sections 44. The plurality of fourth sections 42 and the plurality of fifth sections 44 are respectively positioned at either side of the sixth section 46 (as shown in FIG. 3, the plurality of fourth sections 42 are positioned at the upper side of the sixth section 46, and the plurality of fifth sections 44 are positioned at the lower side of the sixth section 46). The plurality of fourth sections 42 and the plurality of fifth sections 44 respectively develop along a specific contour (such as a contour with turns, curves, or other non-straight lines), and consequently form a part of a ring type structure (such as a square ring type structure shown in FIG. 3).

As shown in FIG. 3, the plurality of first sections 36 and the plurality of fourth sections 42 interdigitate with each other in parallel, and the plurality of second sections 38 and the plurality of fifth sections 44 interdigitate with each other in parallel. More specifically, a layout pattern of the odd metal layers 30 shown in FIG. 3 is formulated along a plurality of square (or rectangular) ring type contours, with larger outer ones and smaller inner ones, wherein the most outer branch of the plurality of second sections 38 makes up a part of a ring type structure at the lower side of the third section 40 and the sixth section 46 by developing along the most outer (i.e., the largest) one of the above ring type contours. Similarly, the most outer branch of the plurality of fourth sections 42 makes up a part of a ring type structure at the upper side of the third section 40 and the sixth section 46 by developing along the most outer (i.e., the largest) one of the above ring type contours. Since the branch of the plurality of second sections 38 and the branch of the plurality of fourth sections 42 mentioned above develop along the same ring type contour (i.e., the most outer ring type contour), the capacitance effect contributed by these two branches will be far more symmetrical than the conventional semiconductor capacitor structures in terms of geometrical scheme.

In addition, the most outer branch of the plurality of first sections 36 makes up a part of a ring type structure at the upper side of the third section 40 and the sixth section 46 by developing along the second outer (i.e., the second largest) one of the above-mentioned ring type contours. Similarly, the most outer branch of the plurality of fifth sections 44 makes up a part of a ring type structure at the lower side of the third section 40 and the sixth section 46 by developing along the second outer (i.e., the second largest) one of the above ring type contours. Since the branch of the plurality of first sections 36 and the branch of the plurality of fifth sections 44 mentioned above develop along the same ring type contour (i.e., the second outer ring type contour), the capacitance effect contributed by these two branches will be far more symmetrical than the conventional semiconductor capacitor structures in terms of geometrical scheme.

As shown in FIG. 3, each branch of the plurality of second sections 38 and the plurality of fourth sections 42 and each branch of the plurality of first sections 36 and the plurality of fifth sections 44 subsequently forms along the various ring type contours, so as to make up a parallel interdigitated structure composed of the plurality of first sections 36 and the plurality of fifth sections 44 along the specific contours at the upper side of the third section 40 and the sixth section 46, and make up another parallel interdigitated structure composed of the plurality of second sections 38 and the plurality of fourth sections 42 along the specific contours at the lower side of the third section 40 and the sixth section 46. In this embodiment, since the semiconductor capacitor structure of the present invention possesses a characteristic of having each branch of the plurality of parallel interdigitated sections develop along the specific ring type contours, the semiconductor capacitor structure of the present invention can attain the optimal geometrical symmetry and have maximum unit capacitance.

As shown in FIG. 4, the even metal layer 50 includes a third portion 52 and a fourth portion 54 in this embodiment, wherein the third portion 52 has the same geometrical layout pattern implementation as the first portion 32 in the odd metal layer 30, and is aligned with and positioned above (and/or below) the first portion 32; the fourth portion 54 also has the same geometrical layout pattern implementation as the second portion 34 in the odd metal layer 30, and is aligned with and positioned above (and/or below) the second portion 34. In other words, the capacitor structure of the even metal layer 50 is a duplicate of the capacitor structure of the odd metal layer 30 in this embodiment. In addition, the first portion 32 in the odd metal layer 30 and the third portion 52 in the even metal layer 50 are electrically connected to each other through via plugs at the third section 40 (such as a protruding part on the left-hand side) in this embodiment, so as to make up a first electrode of the semiconductor capacitor structure. Similarly, the second portion 34 in the odd metal layer 30 and the fourth portion 54 in the even metal layer 50 are electrically connected to each other through via plugs at the sixth section 46 (such as a protruding part on the right-hand side) in this embodiment, so as to make up a first electrode of the semiconductor capacitor structure. In this way, the capacitance value of each of the metal layers can be summed up via the parallel connection.

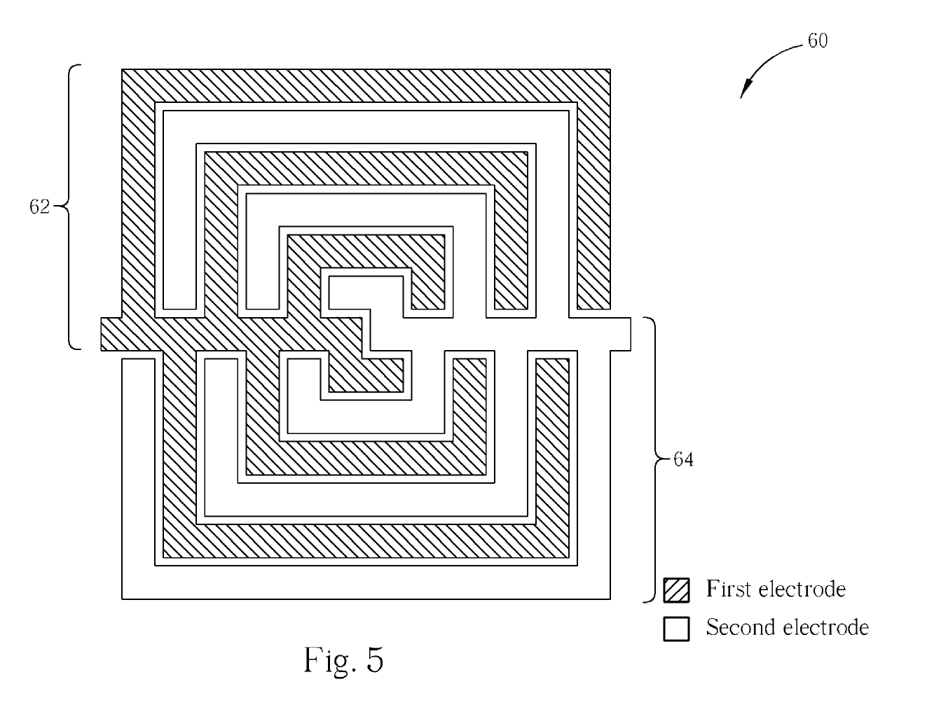

Please refer to FIG. 5. FIG. 5 is a simplified diagram of another even metal layer 60 in accordance with another embodiment of the present invention, which, when implemented together with the odd metal layer 30, formulates a semiconductor capacitor structure. As shown in FIG. 5, the geometrical layout pattern implementation of the even metal layer 60 is made up by flipping the odd metal layer 30 along an extending axis of the third section 40 and the sixth section 46, and is aligned with the geometrical layout pattern implementation of the odd metal layer 30 and positioned above (and/or below) the odd metal layer 30. Similarly, the first portion 32 in the odd metal layer 30 and the fifth portion 62 in the even metal layer 60 are electrically connected to each other through via plugs at the third section 40 (such as a protruding part on the left-hand side) in this embodiment, so as to make up a first electrode of the semiconductor capacitor structure. The second portion 34 in the odd metal layer 30 and the sixth portion 64 in the even metal layer 60 are electrically connected to each other through via plugs at the sixth section 46 (such as a protruding part on the right-hand side) in this embodiment, so as to make up a first electrode of the semiconductor capacitor structure. In this way, in addition to the summed-up capacitance value of each of the metal layers via the parallel connection, there will be an even higher parasitic capacitance value resulting from the parallel interdigitated structure observed between every two layers of the metal layers.

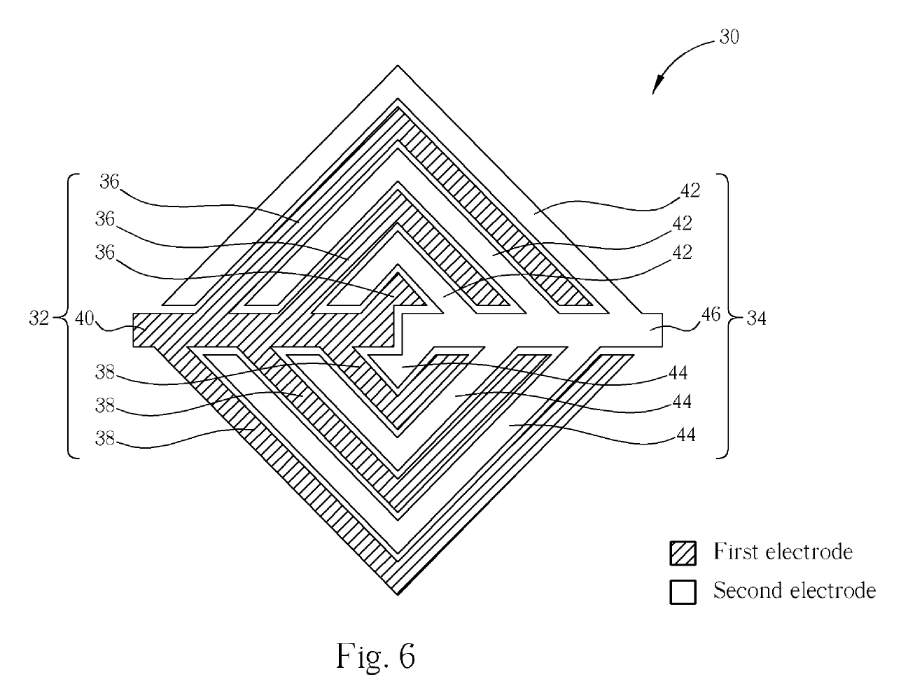

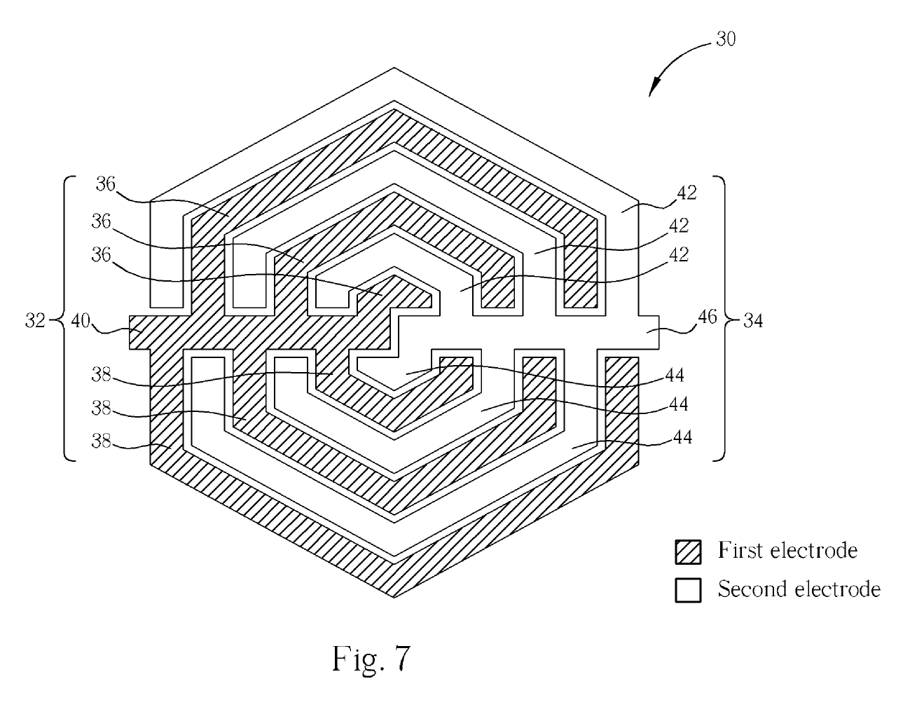

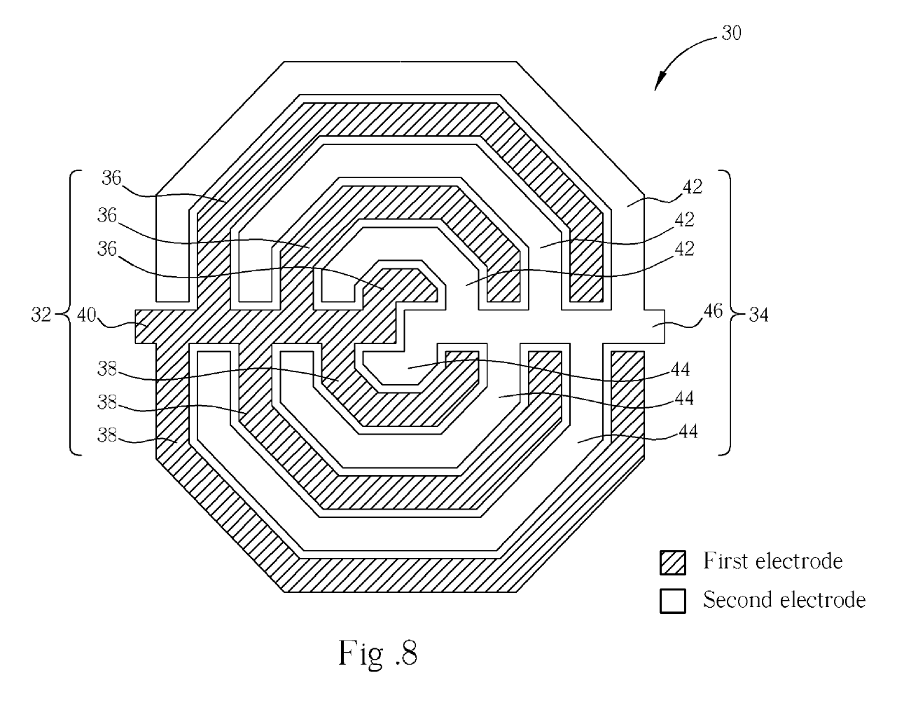

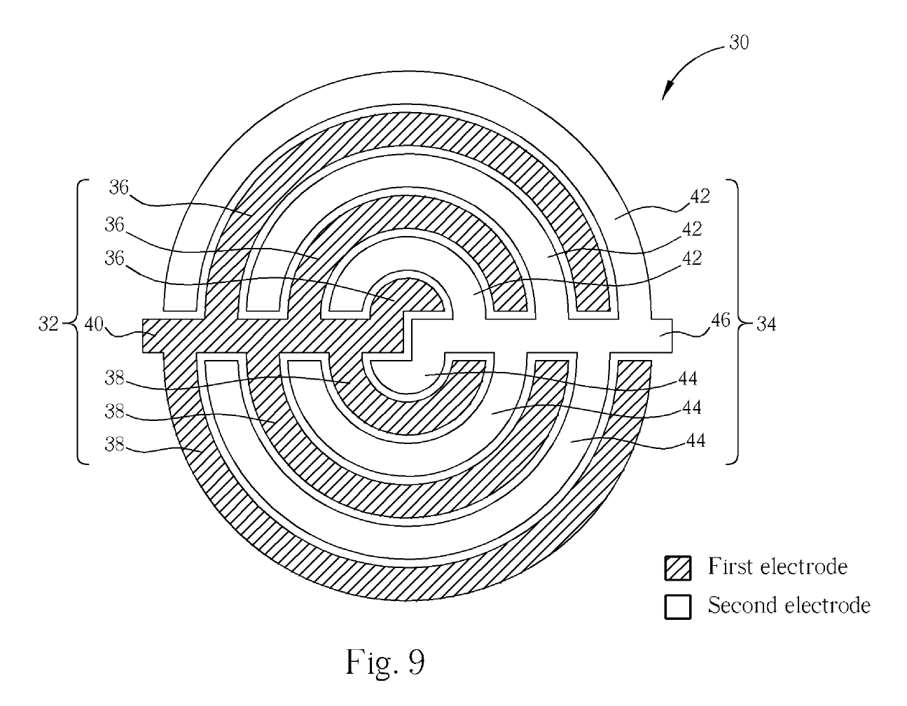

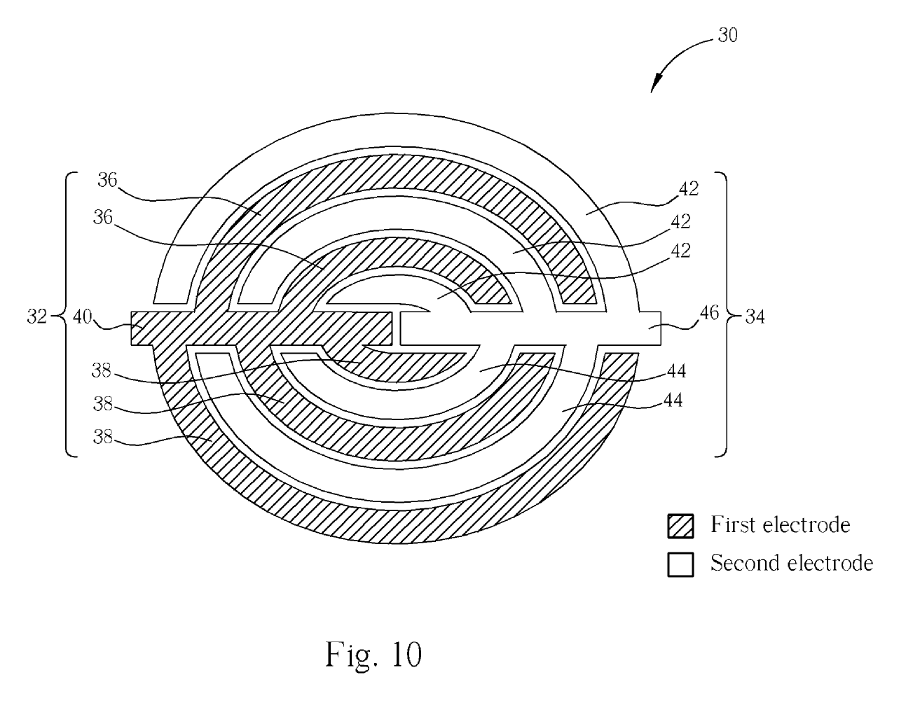

Although the above embodiments illustrate a semiconductor capacitor structure developed along a square or rectangle ring type geometry, those of ordinary skill in the pertinent art should be able to understand that these embodiments are not meant to be limitations of the present invention. For example, the plurality of first sections 36, the plurality of second sections 38, the plurality of fourth sections 42, and the plurality of fifth sections 44 of the odd metal layer 30 and the respective corresponding sections of the even metal layer 50 mentioned above can also develop along a rhombus ring type geometry as shown in FIG. 6, develop along a hexagonal ring type geometry as shown in FIG. 7, develop along an octagonal ring type geometry as shown in FIG. 8, develop along a circular ring type geometry as shown in FIG. 9, or develop along an elliptical ring type geometry as shown in FIG. 10. Please note that the above shapes and embodiments are only for illustration purposes and are not meant to be limitations of the present invention.

In addition, please note that the material utilized by the odd metal layer 30 and the even metal layer 50 can be aluminum, copper, gold, or other metals or nonmetal materials in accordance with the differences in various semiconductor manufacturing processes, and alterations in the use of these materials should all fall within the scope of protection of the present invention.

The semiconductor capacitor structure of the present invention forms an oxide layer between the odd metal layer 30 and the even metal layer 50, and forms and interlaces a plurality of oxide layers and a plurality of metal layers above the odd metal layer 30 or below the even metal layer 50, so as to complete the MOM capacitor structure. The MOM capacitor structure of the present invention does not need additional photomasks above standard CMOS process, which translates into process costs less than the conventional art. In addition, due to improvements in semiconductor process technology, a significantly large number of metal layers can be stacked, and since the distance between the metal layers becomes smaller, a higher unit capacitance can be attained.

Those skilled in the art will readily observe that numerous modifications and alterations of the device and method may be made while retaining the teachings of the invention.

What is claimed is:

1. A semiconductor capacitor structure, comprising:
a first metal layer, comprising:
a first portion, comprising:
a plurality of first sections arranged in parallel to one another, the plurality of first sections having turns or curves;
a plurality of second sections arranged in parallel to one another, the plurality of second sections having turns or curves; and
a third section, coupled to the plurality of first sections and the plurality of second sections; and
a second portion, comprising:
a plurality of fourth sections arranged in parallel to one another, the plurality of fourth sections having turns or curves;
a plurality of fifth sections arranged in parallel to one another, the plurality of fifth sections having turns or curves; and
a sixth section, coupled to the plurality of fourth sections and the plurality of fifth sections;
wherein the plurality of first sections and the plurality of fourth sections interdigitate with each other in parallel, and the plurality of second sections and the plurality of fifth sections interdigitate with each other in parallel;
a second metal layer, comprising:
a third portion, comprising:
a plurality of seventh sections arranged in parallel to one another, the plurality of seventh sections having turns or curves;
a plurality of eighth sections arranged in parallel to one another, the plurality of eighth sections having turns or curves; and
a ninth section, coupled to the plurality of seventh sections and the plurality of eighth sections; and
a fourth portion, comprising:
a plurality of tenth sections arranged in parallel to one another, the plurality of tenth sections having turns or curves;
a plurality of eleventh sections arranged in parallel to one another, the plurality of eleventh sections having turns or curves; and
a twelfth section, coupled to the plurality of tenth sections and the plurality of eleventh sections;
wherein the plurality of seventh sections and the plurality of tenth sections interdigitate with each other in parallel, and the plurality of eighth sections and the plurality of eleventh sections interdigitate with each other in parallel; and
a dielectric layer, formed between the first metal layer and the second metal layer.

2. The semiconductor capacitor structure of claim 1, wherein the first portion and the third portion have horizontal symmetry with each other, the second portion and the fourth portion have horizontal symmetry with each other, the first portion and the third portion constitute a part of a first electrode of the semiconductor capacitor structure, and the second portion and the fourth portion constitute a part of a second electrode of the semiconductor capacitor structure.

3. The semiconductor capacitor structure of claim 1, wherein the first portion and the third portion have horizontal symmetry with each other, the second portion and the fourth portion have horizontal symmetry with each other, the first portion and the fourth portion constitute a part of a first electrode of the semiconductor capacitor structure, and the second portion and the third portion constitute a part of a second electrode of the semiconductor capacitor structure.

4. The semiconductor capacitor structure of claim 1, wherein the plurality of first sections, the plurality of second sections, the plurality of fourth sections, the plurality of fifth sections, the plurality of seventh sections, the plurality of eighth sections, the plurality of tenth sections, and the plurality of eleventh sections constitute a part of a polygon, an ellipse, or a circle.

5. The semiconductor capacitor structure of claim 1, wherein a material of the second metal layer is aluminum, copper, or gold.

6. The semiconductor capacitor structure of claim 1, wherein a material of the first metal layer is aluminum, copper, or gold.

7. The semiconductor capacitor structure of claim 1, being a metal-oxide-metal (MOM) capacitor structure.

8. A metal layer layout applied to a semiconductor capacitor structure, comprising:
a metal layer, comprising:
a first portion, comprising:
a plurality of first sections arranged in parallel to one another, the plurality of first sections having turns or curves;
a plurality of second sections arranged in parallel to one another, the plurality of second sections having turns or curves; and
a third section, coupled to the plurality of first sections and the plurality of second sections; and
a second portion, comprising:
a plurality of fourth sections arranged in parallel to one another, the plurality of fourth sections having turns or curves;
a plurality of fifth sections arranged in parallel to one another, the plurality of fifth sections having turns or curves; and
a sixth section, coupled to the plurality of fourth sections and the plurality of fifth sections;
wherein the plurality of first sections and the plurality of fourth sections interdigitate with each other in parallel, and the plurality of second sections and the plurality of fifth sections interdigitate with each other in parallel.

9. The semiconductor capacitor structure of claim 8, wherein the plurality of first sections, the plurality of second sections, the plurality of fourth sections, and the plurality of fifth sections constitute a part of a polygon, an ellipse, or a circle.

10. The semiconductor capacitor structure of claim 8, wherein a material of the metal layer is aluminum, copper, or gold.

11. A semiconductor capacitor structure, comprising:
a third section;
a plurality of first sections, wherein each of the first sections is coupled to the third section, and extends outward from a side of the third section and respectively develops along one of a plurality of first contours;
a plurality of second sections, wherein each of the second sections is coupled to the third section, and extends outward from another side of the third section and respectively develops along one of a plurality of second contours;
a sixth section;
a plurality of fourth sections, wherein each of the fourth sections is coupled to the third section, and extends outward from a side of the sixth section and respectively develops along one of a plurality of fourth contours; and
a plurality of fifth sections, wherein each of the fifth sections is coupled to the third section, and extends outward from another side of the sixth section and respectively develops along one of a plurality of fifth contours.

12. The semiconductor capacitor structure of claim 11, wherein the plurality of first sections and the plurality of fourth sections interdigitate with each other in parallel, and the plurality of second sections and the plurality of fifth sections interdigitate with each other in parallel.

13. The semiconductor capacitor structure of claim 11, wherein the plurality of first sections are arranged in parallel to one another, the plurality of second sections are arranged in parallel to one another, the plurality of fourth sections are arranged in parallel to one another, and the plurality of fifth sections are arranged in parallel to one another.

14. The semiconductor capacitor structure of claim 1 1, wherein one of the plurality of first contours and one of the plurality of fifth contours are a part of a same ring type contour.

15. The semiconductor capacitor structure of claim 14, wherein the ring type contour is a square or a rectangle.

16. The semiconductor capacitor structure of claim 14, wherein the ring type contour is a circle or an ellipse.

17. The semiconductor capacitor structure of claim 14, wherein the ring type contour is a polygon having even sides.

18. The semiconductor capacitor structure of claim 12, wherein the plurality of first sections, the plurality of second sections, and the third section constitute a part of a first electrode of the semiconductor capacitor structure, and the plurality of fourth sections, the plurality of fifth sections, and the sixth section constitute a part of a second electrode of the semiconductor capacitor structure.

19. The semiconductor capacitor structure of claim 12, wherein the plurality of first sections, the plurality of second sections, the third section, the plurality of fourth sections, the plurality of fifth sections, and the sixth section are all made of metal.

20. The semiconductor capacitor structure of claim 12, wherein the plurality of first contours, the plurality of second contours, the plurality of fourth contours, and the plurality of fifth contours all have turns or curves.
